(19) United States
(12) Patent Application Publication
(10) Pub. No.: US 2024/0186174 A1
(43) Pub. Date: Jun. 6, 2024

(54) APPARATUS FOR MANUFACTURING SEMICONDUCTOR DEVICES AND METHOD OF MANUFACTURING SEMICONDUCTOR DEVICES

(71) Applicant: SAMSUNG ELECTRONICS CO., LTD., Suwon-si (KR)

(72) Inventors: Fumitaka MOROISHI, Yokohama City (JP); Tatsuya ISHIMOTO, Yokohama City (JP)

(21) Appl. No.: 18/509,104

(22) Filed: Nov. 14, 2023

(30) Foreign Application Priority Data
Dec. 1, 2022 (JP) 2022-192614
Jan. 11, 2023 (KR) 10-2023-0003941

(51) Int. Cl. H01L 21/683; H01L 21/67

(52) U.S. Cl. CPC H01L 21/6838; H01L 21/67017; H01L 21/67092; H01L 21/67288; H01L 21/6836; H01L 2221/68327

(57) ABSTRACT

In order to provide a semiconductor manufacturing apparatus capable of realizing highly reliable mounting, a semiconductor manufacturing apparatus includes a pick-up head having a plurality of ejection holes for ejecting gas and a plurality of suction holes for suctioning the gas provided in a holding surface that holds a chip. A warpage measurement portion is configured to measure warpage of the chip held by the pick-up head, and a controller is configured to control at least one of a gas supply flow rate from the plurality of ejection holes and a suction flow rate from the plurality of suction holes in response to the measured warpage of the chip.

### PRIORITY STATEMENT

This application claims priority under 35 U.S.C. § 119 to Japanese Patent Application No. 2022-192614, filed on Dec. 1, 2022, and Korean Patent Application No. 10-2023-0003941, filed on Jan. 11, 2023 in the Korean Intellectual Property Office (KIPO), the disclosures of which are herein incorporated by reference in their entireties.

### BACKGROUND

### 1. Field

Example embodiments relate to a manufacturing apparatus for a semiconductor device and a manufacturing method for a semiconductor device. More particularly, example embodiments relate to a manufacturing apparatus for a semiconductor device including a three-dimensional mounting apparatus for stacking and bonding semiconductor chips or interposers, and a manufacturing method for a semiconductor device using the same.

### 2. Description of the Related Art

In order to achieve low power consumption and high driving speed, multilayering of semiconductor devices is progressing. A process of stacking semiconductor chips such as Chip on Chip (CoC) and Chip on Wafer (CoW), or a chip bonding process of mounting a semiconductor package is changing from a conventional connection method between contacts through wire bonding to a connection method using a flip chip or through-silicon via (TSV).

In the conventional connection method between contacts through wire bonding, bonding accuracy of several tens of m (micrometers) was sufficient, but in a flip chip in which bumps and pads are directly contacted, precision of several m is required, and in particular, sub-μm precision is required for chip bonding using silicon through electrodes. In addition, since metals are directly joined, high temperature and high pressure tend to be required at the time of joining. In a high-precision chip bonding apparatus, minute changes in mechanical and thermal structures become factors that hinder accuracy.

Further, in direct bonding without materials related to bonding such as bumps and solder, since electrodes are directly bonded to each other with a narrow pitch, bonding accuracy of several hundred nanometers or less is required. Direct bonding is a technique of activating the bonded surfaces with plasma or the like and aligning the activated surfaces to perform bonding. When bonding is performed, if a foreign substance is mixed in the bonding surface, a gap may be generated, which may cause a void to be formed after bonding. If pick-up is performed by contacting a pattern surface of the chip, foreign substances may adhere to the mounting surface and may cause bonding failure. Therefore, a method of picking up a chip without contacting the bonding surface is preferred.

Japanese Patent Laid-open Publication No. 2022-072566 (Patent Document 1) discloses a semiconductor manufacturing apparatus that picks up chips in a non-contact manner. The semiconductor manufacturing apparatus described in Patent Document 1 has a plurality of pressurization holes for ejecting gas and a plurality of suction holes for sucking gas, and handles chips through air.

Since the semiconductor manufacturing apparatus described in Patent Document 1 holds the chip by pressurizing and suction, it is possible to suppress foreign matter from entering the bonding surface. However, bending may occur in the chip due to pressure or suction for holding the semiconductor chip in a non-contact manner, or stress of the chip. In this way, when bonding is performed with warpage occurring in the chip, there is a problem that voids are generated and residual stress remains.

### SUMMARY

Example embodiments provide a semiconductor manufacturing apparatus capable of realizing highly reliable mounting.

Example embodiments provide a method of manufacturing a semiconductor device using the above-described semiconductor manufacturing apparatus.

According to example embodiments, a manufacturing apparatus for a semiconductor device includes a pick-up head having a holding surface configured to hold a bonding component. The holding surface includes a plurality of ejection holes through which gas is ejected, and a plurality of suction holes through which the gas is suctioned. A warpage measurement device is configured to measure warpage of the bonding component held by the pick-up head, and a controller is configured to control at least one of a supply flow rate of the gas ejected through the plurality of ejection holes and a suction flow rate of the gas suctioned through the plurality of suction holes in response to the measured warpage of the bonding component.

In example embodiments, the holding surface may be divided into a plurality of regions that are outwardly spaced from a center of the holding surface, and the controller may control the supply flow rate of the gas from the plurality of ejection holes and the suction flow rate from the plurality of suction holes for each of the plurality of regions.

In example embodiments, the holding surface includes a positioning portion having a gas supply hole and an exhaust hole, wherein the positioning portion is configured to position the bonding component by flowing gas from the gas supply hole to the exhaust hole.

In example embodiments, the positioning portion may include a groove in the holding surface, and the gas supply hole and the exhaust hole may be in the groove.

In example embodiments, the manufacturing apparatus may further include a bonding head configured to receive the bonding component from the pick-up head and bond the bonding component to a component. When the bonding head receives the bonding component from the pick-up head, the controller is configured to control at least one of the supply flow rate and the suction flow rate to change a shape of the bonding component held by the pick-up head according to a shape of an adsorption surface of the bonding head.

According to example embodiments, in a method of manufacturing a semiconductor device, a bonding component is held by a pick-up head that has a plurality of ejection holes for ejecting gas and a plurality of suction holes for suctioning gas, provided in a holding surface that holds the bonding component. Warpage of the bonding component held by the pick-up head is measured. At least one of a supply flow rate of the gas from the plurality of ejection holes and a suction flow rate from the plurality of suction holes is controlled in response to the measured warpage of the bonding component.

In example embodiments, the holding surface may be divided into a plurality of regions that are outwardly spaced from the center of the holding surface, and the supply flow rate of the gas from the plurality of ejection holes and the suction flow rate from the plurality of suction holes may be controlled for each of the plurality of regions.

In example embodiments, the holding surface may include a positioning portion having a gas supply hole and an exhaust hole, and the method may further include positioning the bonding component via the positioning portion by flowing the gas from the gas supply hole to the exhaust hole.

In example embodiments, the positioning portion may include a groove in the holding surface, and the gas supply hole and the exhaust hole are in the groove.

In example embodiments, the method may further include transferring the bonding component from the pick-up head to a bonding head that is configured to bond the bonding component to a component. When the bonding head receives the bonding component from the pick-up head, at least one of the supply flow rate and the suction flow rate is controlled to change a shape of the bonding component held by the pick-up head according to a shape of an adsorption surface of the bonding head.

According to example embodiments, a manufacturing apparatus for a semiconductor device includes a pick-up head configured to pick up and hold a bonding component. The pick-up head includes a holding surface that is configured to adsorb and hold the bonding component. The holding surface includes a plurality of ejection holes through which gas is ejected, and a plurality of suction holes through which gas is suctioned. The plurality of ejection holes and the plurality of suction holes are arranged in a plurality of regions of the holding surface, wherein the plurality of regions include a central region at a center of the holding surface and a plurality of spaced apart concentric regions extending around the central region.

In example embodiments, two or more ejection holes are adjacent each one of the plurality of suction holes in each of the plurality of regions.

In example embodiments, the plurality of spaced apart concentric regions include a first concentric region that is outwardly spaced apart from the central region and that extends around the central region.

In example embodiments, the plurality of spaced apart concentric regions further include second and third concentric regions, wherein the second concentric region is outwardly spaced apart from the first concentric region and extends around the first concentric region, and wherein the third concentric region is outwardly spaced apart from the second concentric region and extends around the second concentric region.

In example embodiments, the holding surface includes at least one positioning portion having at least one gas supply hole and at least one exhaust hole, wherein the at least one positioning portion is configured to position the semiconductor chip by flowing gas from the at least one gas supply hole to the at least one exhaust hole.

In example embodiments, the at least one positioning portion includes a first positioning portion that extends along a first direction, and a second positioning portion that extends along a second direction that is transverse to the first direction.

In example embodiments, the first positioning portion and the second positioning portion are each located between adjacent concentric regions.

In example embodiments, the at least one positioning portion includes a groove in the holding surface, wherein the at least one gas supply hole and the at least one exhaust hole are in the groove, and wherein a size of the at least one exhaust hole is larger than a size of the at least one gas supply hole.

In example embodiments, the groove includes opposite first and second ends, wherein the at least one gas supply hole includes a plurality of gas supply holes adjacent the first end, and wherein the at least one exhaust hole includes a plurality of exhaust holes adjacent the second end.

In example embodiments, the holding surface includes opposite first and second edges, and opposite third and fourth edges. The at least one positioning portion includes a first positioning portion that extends along and is adjacent to the first edge, a second positioning portion that extends along and is adjacent to the second edge, a third positioning portion that extends along and is adjacent to the third edge, and a fourth positioning portion that extends along and is adjacent to the fourth edge.

According to example embodiments, it may be possible to realize highly reliable mounting.

### BRIEF DESCRIPTION OF THE DRAWINGS

Example embodiments will be more clearly understood from the following detailed description taken in conjunction with the accompanying drawings. FIGS. 1 to 14 represent non-limiting, example embodiments as described herein.

FIG. 1 is a diagram schematically illustrating an apparatus for manufacturing a semiconductor device in accordance with example embodiments.

FIG. 2 is a diagram illustrating a state in which a chip is picked up by a picker of FIG. 1.

FIG. 3 is a view illustrating a state in which a surface shape of the chip picked up by the picker of FIG. 1 is measured.

FIG. 4 is a diagram illustrating a configuration of a holding surface of the picker of FIG. 1

FIG. 5 is a flowchart illustrating a method of manufacturing a semiconductor device in accordance with example embodiments.

FIG. 6 is a diagram illustrating a method of manufacturing a semiconductor device in accordance with example embodiments.

FIG. 7 is a diagram showing a state in which warpage of a chip is suppressed by the picker of FIG. 1.

FIG. 8 is a diagram illustrating an example of an arrangement of positioning portions provided in the picker of FIG. 1.

FIG. 9 is a cross-sectional view taken along the line IX-IX in FIG. 8.

FIG. 10 is a diagram illustrating an example of positioning a chip by the positioning portion

FIG. 11 is a diagram showing another example of a positioning portion.

FIG. 12 is a diagram showing another example of a positioning portion.

FIG. 13 is a diagram illustrating another example of an arrangement of a positioning portion provided in the picker of FIG. 1.

FIG. 14 is a diagram illustrating a method of manufacturing a semiconductor device in accordance with example embodiments.

### DETAILED DESCRIPTION OF EXAMPLE EMBODIMENTS

Hereinafter, example embodiments will be explained in detail with reference to the accompanying drawings.

Example embodiments may relate to a manufacturing apparatus for a semiconductor device including a 3D mounting device (chip bonder or die bonder) configured to stack and bond a relay component such as a semiconductor chip or an interposer. The manufacturing apparatus for the semiconductor device according to example embodiments may stack a thin chip having a thickness of, for example, 30 μm or less and directly bond electrodes without using an intermediate material such as solder. In particular, example embodiments may relate to a picker configured to peel and pick up such a thin chip from a dicing tape and a chip handling method.

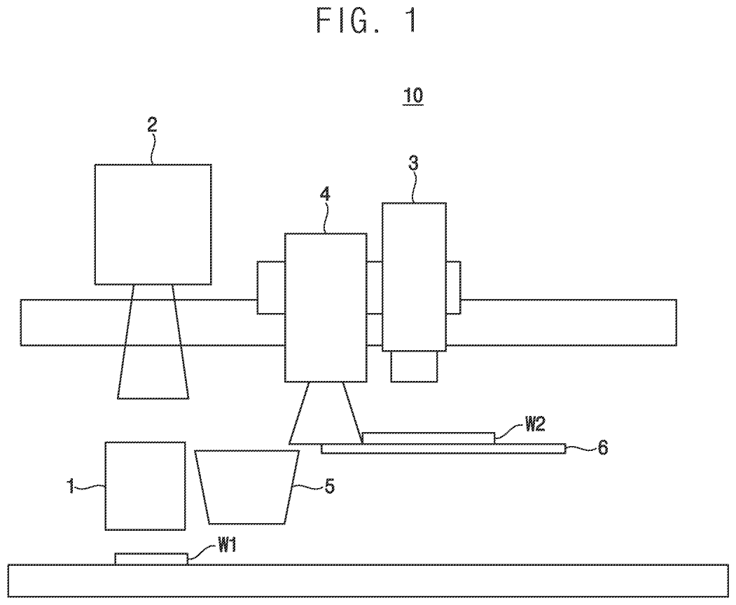

FIG. 1 is a view schematically illustrating a manufacturing apparatus for a semiconductor device 10 in accordance with example embodiments. The manufacturing apparatus for the semiconductor device 10 as illustrated in FIG. 1 may bond (mount) a chip W1 to a substrate W2. In addition, the chip W1 may be an example of a bonding component, and may be, for example, a substantially rectangular flat plate-shaped semiconductor chip. In addition, the substrate W2 may be an example of a component to be joined, and may be, for example, a semiconductor substrate.

As illustrated in FIG. 1, the manufacturing apparatus for the semiconductor device 10 may include a picker 1, a warpage measurement portion 2, a bonding head 3, a camera 4, an optical portion 5, and a bonding stage 6. Additionally, although not illustrated in the figures, the manufacturing apparatus for the semiconductor device 10 may further include a controller having a function of controlling operations thereof. The controller will be described later.

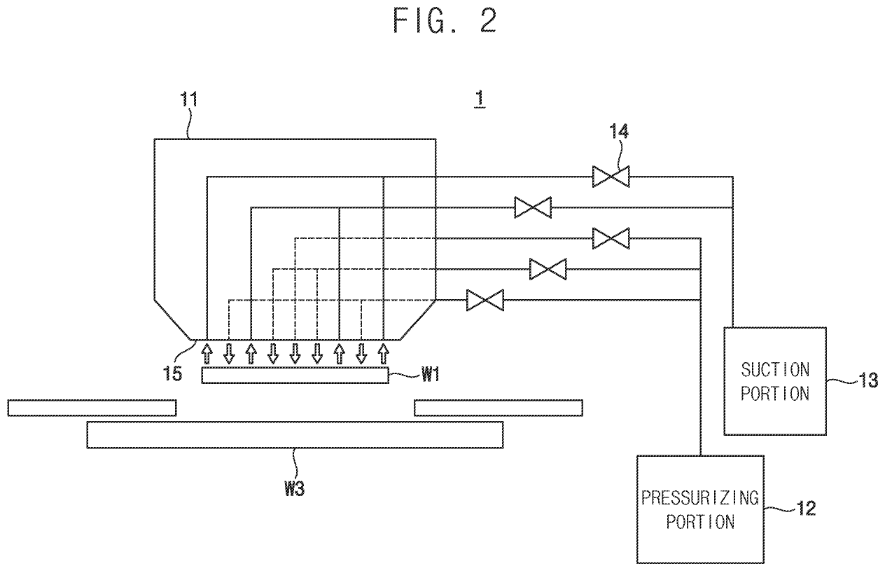

The picker 1 may pick up and hold the chip W1 in a non-contact manner. The picker 1 may be, for example, a flip chip picker that picks up an individual chip diced from a semiconductor wafer by peeling the individual chip from a dicing tape W3 (FIG. 2) that adhesively fixes the individual chip, and reverses a front surface and a backside surface of the individual chip. The picker 1 may pick up the chip W1 from a chip tray. The picker 1 may pick up the chip W1 without contacting a pattern surface of the chip W1.

The warpage measurement portion 2 may measure the warpage of the chip held by the picker 1 in a non-contact manner. The warpage measurement portion 2 may include, for example, a 3D camera, a laser sensor, etc., that is capable of measuring a three-dimensional surface shape. The warpage measurement portion 2 may output the measurement result of the warpage of the chip W1 to the controller as described later.

The bonding head 3 may accommodate the chip W1 picked up by the picker 1 and adsorb and hold the chip W1. Then, the bonding head 3 may carry the held chip W1 onto the bonding stage 6 and then at the same time mount the chip W1 on the substrate W2.

The camera 4 may be installed in the bonding head 3. The camera 4 may move together with the bonding head 3. The camera 4 may be a charge coupled device (CCD) or a complementary metal oxide semiconductor (CMOS) sensor. The camera 4 may capture an image of the chip W1 on the optical portion 5 and an image of the substrate W2 on the bonding stage 6.

In the example shown in FIG. 1, only one camera 4 may be used from pick-up of the chip W1 until the chip W1 is bonded on the substrate W2. One camera 4 may capture images of the chip W1 and the substrate W2 to acquire positional information of each of the chip and the substrate.

In particular, the camera 4 may photograph the chip W1 held by the bonding head 3 through the optical portion 5 when the bonding head 3 holds the chip W1, to obtain position information. The optical portion 5 may be an optical system that is configured to reverse an optical path of the camera 4. The optical portion 5 may make it possible to image the surface (mounting surface) opposite to the held surface of the chip W1 adsorbed and held by the bonding head 3. In addition, the camera 4 may capture an image of the substrate W2 placed on the bonding stage 6 when mounting the chip W1 on the substrate W3, and may obtain positional information of the substrate W2 on which the chip W1 is to be mounted.

The substrate W2 may be adsorbed and held on the bonding stage 6. The bonding stage 6 may be configured to correct a positional relationship between the chip W1 and the substrate W2, based on the image of the chip W1 captured by the camera 4 through the optical portion 5 and the image of the substrate W2 captured by the camera 4.

Regarding the correction of the positional relationship between the chip W1 and the substrate W2 using the camera 4 and the optical portion 5, the method described in Japanese Patent Laid-open Publication No. 2022-106192, which is incorporated herein by reference in its entirety, may be employed. Additionally, the chip W1 and the substrate W2 may be aligned using a plurality of cameras.

Hereinafter, a configuration of the picker 1 will be described with reference to FIGS. 2, 3 and 4.

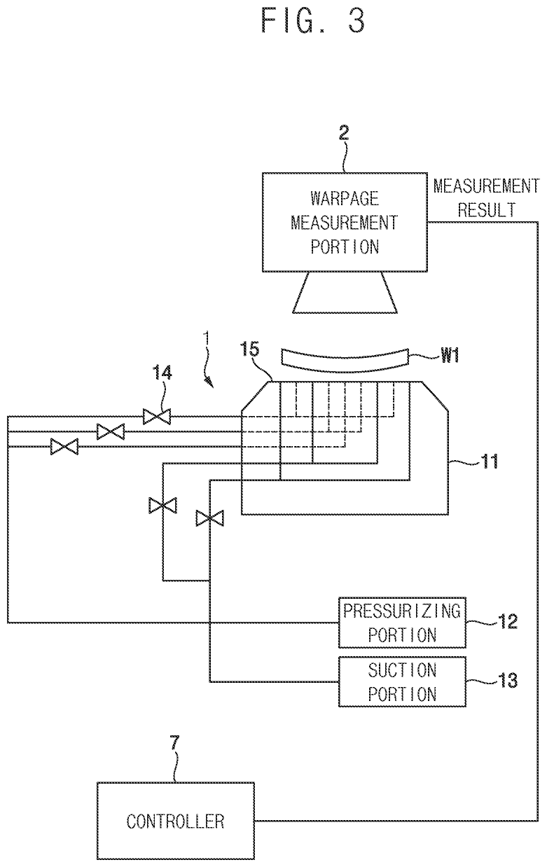

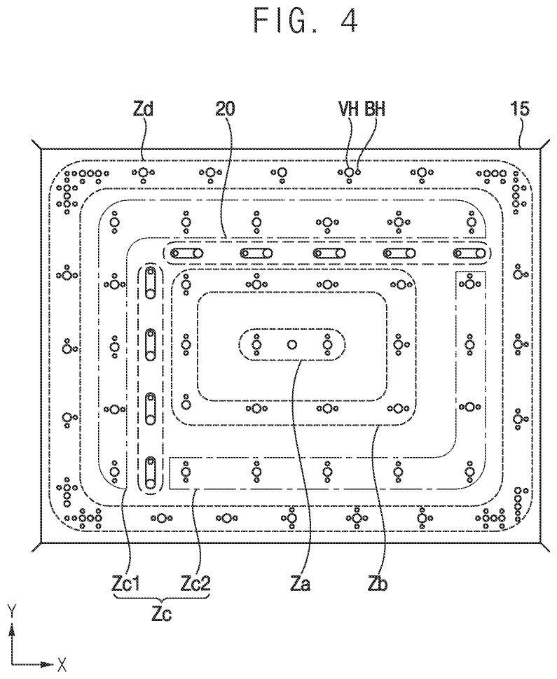

FIG. 2 is a diagram illustrating a state in which the chip W1 is being picked up by the picker 1 of FIG. 1. FIG. 3 is a view illustrating a state in which a surface shape of the inverted chip W1 after being picked up by the picker 1 of FIG. 1 is being measured. FIG. 4 is a diagram illustrating a configuration of a holding surface of the picker of FIG. 1.

As illustrated in FIG. 2, the picker 1 may include a pick-up head 11, a pressurizing portion (i.e., a pressurized gas supply) 12, a suction portion (i.e., a vacuum system) 13 and a valve 14. The pick-up head 11 may have a holding surface 15 which is planar and configured to hold the chip W1.

A plurality of ejection holes BH and a plurality of suction holes VH may be provided in the holding surface 15. The ejection hole BH may be an aperture through which gas is ejected toward the surface holding the chip W1 when the pick-up head 11 handles the chip W1. The suction hole VH may be an aperture through which gas is suctioned from the surface side when the pick-up head 11 handles the chip W1.

In FIG. 4, an example of the arrangement of the ejection holes BH and the suction holes VH in the holding surface 15 is illustrated. In the example shown in FIG. 4, each ejection hole BH may be disposed near a suction hole VH. In this example, a size of a suction hole VH may be greater than a size of an ejection hole BH. The suction holes VH may have a circular shape with a diameter of 0.5 mm, for example. The ejection holes BH may have a circular shape with a diameter of 0.05 mm, for example. The sum of cross-sectional areas of the plurality of suction holes VH may be greater than the sum of cross-sectional areas of the plurality of ejection holes BH. In addition, the shapes of the ejection holes BH and the suction holes VH when viewed in plan view are not limited to circular shapes, and may have shapes such as ellipses and polygons.

Additionally, for the arrangement of the ejection holes BH and the suction holes VH, the technique described in Japanese Laid-open Patent Publication No. 2022-72566, which is incorporated herein by reference in its entirety, may be employed. That is, the suction holes VH may be provided at least at a position near the apex of the holding surface 15. Additionally, the suction holes VH may not be disposed outside the chip W1 to be kept non-contact. In addition, the suction holes VH may be provided in a position other than the above.

In the example of FIG. 4, two or more ejection holes BH may be provided for one suction hole VH, as illustrated. In FIG. 4, XY coordinates with the right direction as +X direction and the upper direction as the +Y direction are applied. For example, a total of two ejection holes BH may be disposed in each X direction of one suction hole VH. Additionally, for example, a total of four ejection holes BH may be disposed in each ±X direction and ±Y direction of one suction hole VH. It will be understood that the number or arrangement of the suction holes VH and the ejection holes BH shown in FIG. 4 is illustrative and not limited thereto.

The pressurizing portion (e.g., a pressurized gas supply) 12 may be in fluid communication with the ejection holes BH through a gas supply passage (not shown) provided in the picker 1. The pressurizing portion 12 may be, for example, an electro-pneumatic regulator, and may deliver gas such as air. In addition, examples of the gas may be an inert gas such as nitrogen or a mixed gas. The set pressure of the pressurizing portion 12 may be within the range of 0.2 MPa to 0.6 MPa, for example.

The suction portion (e.g., a vacuum system) 13 may be in fluid communication with the suction holes VH through a gas exhaust passage (not shown) provided in the picker 1, and may suction gas through the suction holes VH to adjust the vacuum pressure. The suction portion 13 may be, for example, an electro-pneumatic regulator. The suction pressure by the suction portion 13 may be within the range of 83 kPa to 70 kPa, for example.

With the above structure, the manufacturing apparatus for the semiconductor device 10 may be configured to hold the chip W1 in a floating state at a constant distance from the holding surface 15 by vacuum adsorption by the suction holes VH disposed in the pickup head 11 and pressurization by the ejection holes BH disposed around the suction hole VH.

In this way, the chip W1 picked up by the picker 1 may be floating on the holding surface 15 of the picker 1. At this time, the thin chip W1 of, e.g., 30 μm or less, may be deformed due to the adsorption or pressurization for floating the chip W1. Additionally, the chip W1 may be bent under the influence of the pattern drawn on the chip W1. Therefore, in example embodiments, warping of the chip W1 held in the picker 1 may be reduced by following configurations.

Referring to FIG. 2, the valve 14 may be disposed in the gas supply passage from the pressurizing portion 12 to the ejection holes BH. The valve 14 in the gas supply passage may be a flow control valve configured to adjust a flow rate of the gas ejected from the ejection holes BH. In addition, the valve 14 may be disposed in the gas exhaust passage from the suction portion 13 to the suction holes VH. The valve 14 in the gas exhaust passage may be a flow control valve configured to adjust a flow rate of the gas suctioned from the suction holes VH.

The opening of the valve 14 may be controlled by the controller 7 shown in FIG. 3. That is, the controller 7 may have a function of controlling a gas supply flow rate from the plurality of ejection holes BH and a suction flow rate from the plurality of suction holes VH.

The controller 7 may independently control the gas supply flow rate of each ejection hole BH and the suction flow rate of each suction hole VH. In addition, the ejection holes BH and the suction holes VH may be disposed in a plurality of regions, and the gas supply flow rate and the suction flow rate may be controlled for each region.

In the example shown in FIG. 4, the holding surface 15 may be divided into four regions Za, Zb, Zc and Zd from the center toward the outside. Additionally, in this example, the region Zc may include sub regions Zc1 and Zc2. For example, the plurality of ejection holes BH and the plurality of suction holes VH are arranged in a plurality of regions of the holding surface that include a central region Za at a center of the holding surface and a plurality of outwardly spaced apart concentric regions Zb, Zc, Zd that extend around the central region, as illustrated in FIG. 4. Each of the regions Za, Zb, Zc and Zd may include a plurality of ejection holes BH and a plurality of suction holes VH, respectively. The controller 7 may control the gas supply flow rate from the ejection holes BH and the suction flow rate from the suction holes VH for each of the plurality of regions Za, Zb, Zc, and Zd. In the illustrated embodiment, the plurality of spaced apart concentric regions include a first concentric region Zb that is outwardly spaced apart from the central region Za and that extends around the central region Za. A second concentric region Zc is outwardly spaced apart from the first concentric region Zb and extends around the first concentric region Zb, and a third concentric region Zd is outwardly spaced apart from the second concentric region Zc and extends around the second concentric region Zc.

For example, a nozzle flapper type valve may be used for the valve 14. Since the nozzle flapper type valve does not have a sliding part and controls the flow rate by elastic deformation of metal, it may be possible to control the flow rate quickly and at high speed. In addition, in case that the area of the path to be controlled is large, a spool type valve having a larger controlled flow rate than the nozzle flapper type valve may be used for the valve 14.

As illustrated in FIG. 3, the warpage measurement result of the chip W1 measured by the warpage measurement portion 2 may be output to the controller 7. The controller 7 may control the valve 14 according to the measurement result, and may control the gas supply flow rate of each gas supply passage and the suction flow rate of each gas exhaust passage.

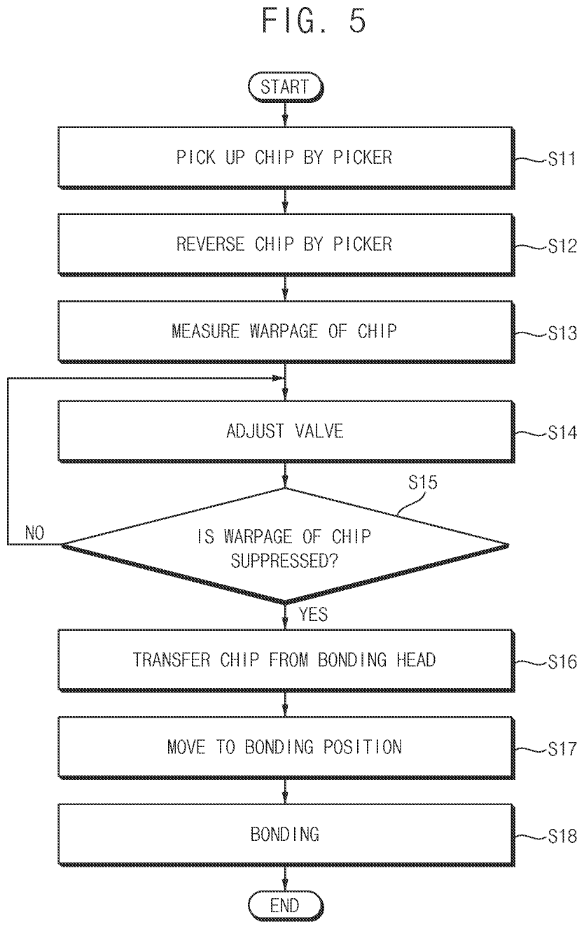

Hereinafter, a method of manufacturing a semiconductor device will be described with reference to FIGS. 5, 6, and 7.

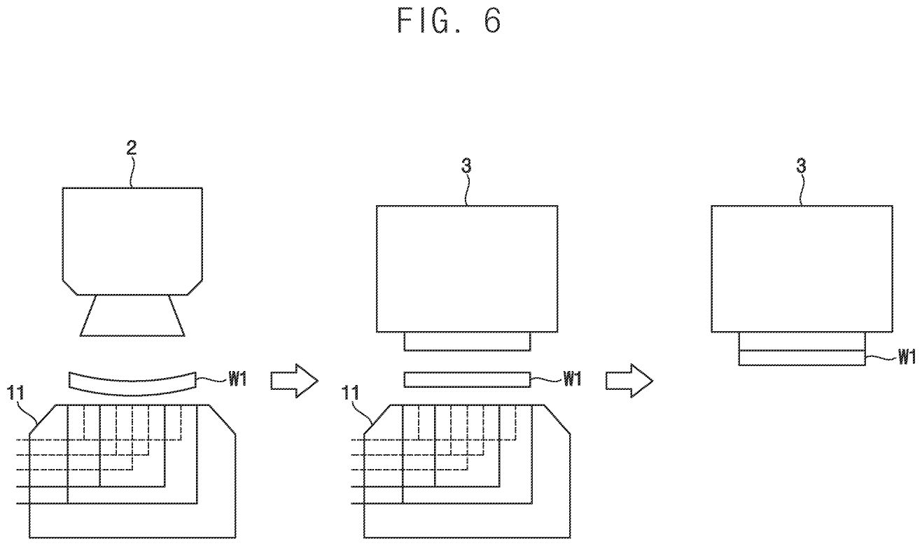

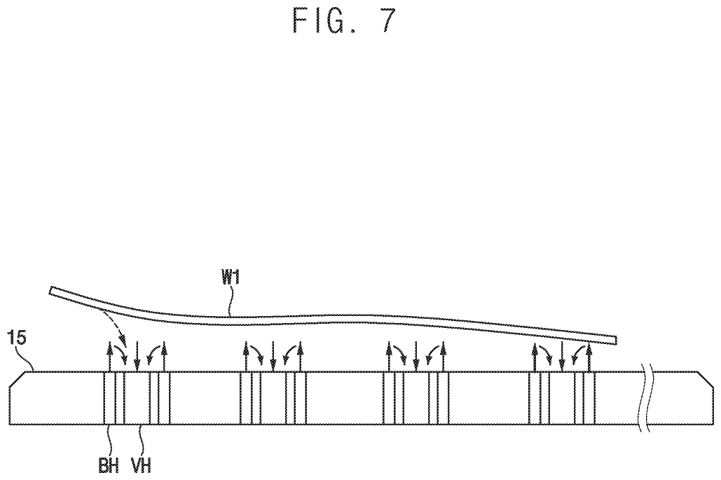

FIG. 5 is a flowchart illustrating a method of manufacturing a semiconductor device in accordance with example embodiments. FIG. 6 is a diagram illustrating a method of manufacturing a semiconductor device in accordance with example embodiments. In FIG. 6, a state of measuring the surface shape of the chip W1 picked up by the picker 1, a state of transferring the chip W1 from the picker 1 to the bonding head 3, and a state in which the chip W1 is adsorbed and held by the bonding head 3 are shown in order from the left. FIG. 7 is a diagram showing a state in which warpage of the chip W1 is suppressed by the picker 1 of FIG. 1.

Before picking up the chip W1 from the dicing tape W3, positions of the ejection holes BH and the suction holes VH relative for keeping the chip W1 in a floating state with respect to the pick-up head 11 may be measured by the warpage measurement portion 2 such as a 3D camera in advance. The position information of the ejection holes BH and the suction holes VH may be registered in the controller 7. Additionally, this location information may be a design value.

As illustrated in FIG. 5, first, the chip W1 may be picked up from the dicing tape W3 by the picker 1 (S11), and may be reversed (S12) (i.e., the orientation of the chip W1 may be reversed). Then, the warpage measurement portion 2 may measure the warpage of the chip W1 held by the picker 1 (S13). This state is shown on the left side of FIG. 6.

The measurement result of the warpage of the chip W1 measured three-dimensionally by the warpage measurement portion 2 may be transmitted to the controller 7. The controller 7 may adjust the opening degree of the valve 14 based on the position of the chip W1 in the pick-up head 11 and the uneven shape of the chip W1 obtained from the measurement result (S14). That is, the controller 7 may determine the valve 14 that executes the control based on the measured shape of the chip W1, and may control the gas supply flow rate or the suction flow rate.

Also, it is known that when a gap between the chip W1 and the holding surface 15 of the pick-up head 11 is around 15 μm, the suction force may become the strongest. For example, at the left end of FIG. 7, when the gap between the chip W1 and the holding surface 15 is wide, the opening of the valve 14 of the gas supply passage may be decreased to reduce the gas supply flow rate, and to strengthen the suction force on the chip W1. Additionally, for example, at the right end of FIG. 7, when the gap between the chip W1 and the holding surface 15 is narrow, the opening of the valve 14 of the gas supply passage may be increased to increase the gas supply flow rate, and to lift the chip W1. In this way, the controller 7 may suppress the warpage of the chip W1 and make it have a flat state. Accordingly, the state shown in the center of FIG. 6 may be obtained.

It may be preferable that the controller 7 controls all the valves 14 together, rather than controlling the valves 14 of each region Za to Zd in parallel. This is because, when each valve 14 is independently controlled, the deformation of the chip W1 at the controlled location affects the chip W1 at the uncontrolled locations, causing interference between controls. By controlling all the valves 14 simultaneously, the adjustment amount of the valves 14 may be made small.

Referring again to FIG. 5, the controller 7 may determine whether or not the warpage of the chip W1 is suppressed to a predetermined value based on the measurement result by the warpage measurement portion 2 (S15). If the warpage of the chip W1 is not suppressed (S15 NO), the process may return to step S14 and the valve 14 may be adjusted. On the other hand, when the warpage of the chip W1 is suppressed (S15 YES), the process may proceed to step S16 and the chip W1 may be transferred from the pick-up head 11 to the bonding head 3. This condition is shown on the right side of FIG. 6. Then, the bonding head 3 may move to a bonding position (S17) and bond the chip W1 to the substrate W2 (S18).

As mentioned above, when a chip that is held in non-contact or contact is transferred to the bonding head, when warpage occurs in the chip, the process of bonding the chip on the substrate may be performed in a state where concavo-convex occurs due to the warpage of the chip, which causes the occurrence of voids.

In contrast, in example embodiments, warpage of the chip W1 may be suppressed, and stability when transferring the chip W1 from the picker 1 to the bonding head 3 may be secured. Additionally, since the process of bonding the chip W1 to the substrate W2 is performed with the bonding head 3 holding the chip W1 in a state where warpage is suppressed in this way, it may be possible to realize highly reliable bonding.

In addition, when the bending states of the plurality of individual chips W1 adhesively fixed to the dicing tape W3 are different, the surface shape may be measured every time the chip W1 is picked up, and controlling of the valve 14 may be executed. On the other hand, when the state of warpage of each of the plurality of individual chips W1 cut from one product, that is, one semiconductor wafer, is the same, it may not be necessary to measure the surface shape each time. For example, the opening degree of the valve 14 may be determined by measuring the surface shape of one chip W1 in advance, and the opening degree of the valve 14 may be applied to another chip W1 to make the corresponding chip W1 flat.

Further, after picking up the chip W1, when a force in the horizontal direction is applied to the chip W1 due to an inclination of the holding surface 15 or a centrifugal force at the time of inversion, the chip W1 may vibrate in the horizontal direction on the pick-up head 11. When vibration occurs in the chip W1, the positional relationship between the ejection hole BH and the suction hole VH for controlling warpage and the chip W1 may be changed, making it difficult to flatten the chip W1. In addition, when transferring the chip W1 to the bonding head 3, positional displacement may occur, which may affect bonding quality.

Accordingly, as illustrated in FIG. 4, a positioning portion 20 may be provided in the holding surface 15 of the pick-up head 11. In this example, two positioning portions 20 may be provided to extend in the X direction and the Y direction. The positioning portion 20 may be provided between the region Zb and the region Zc. The region Zc may be divided into a sub area Zc1 and a sub area Zc2 by the positioning portion 20.

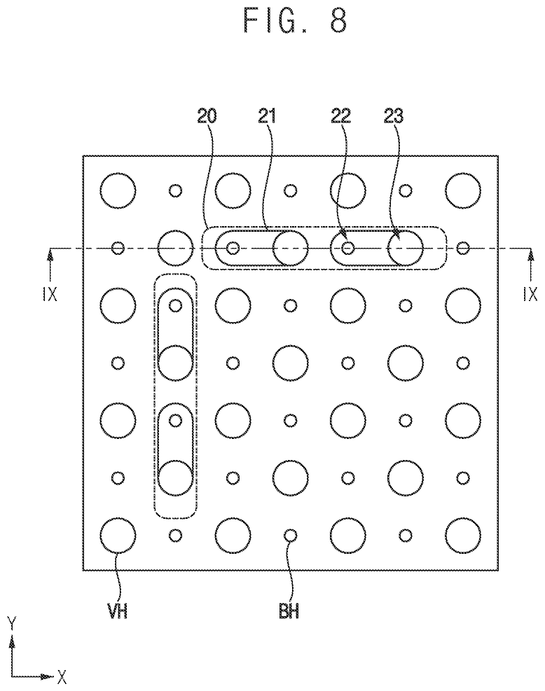

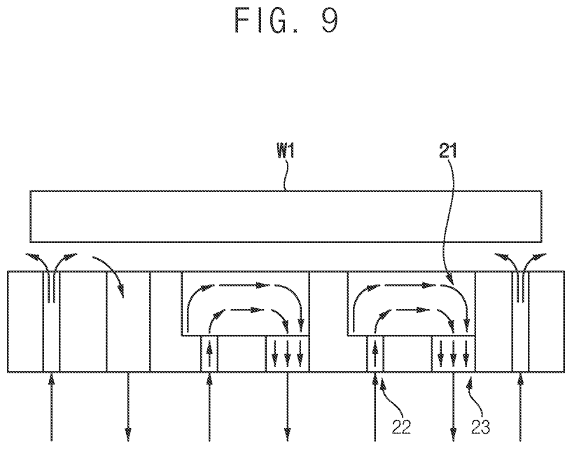

Hereinafter, the positioning portion 20 will be described in detail with reference to FIGS. 8 and 9.

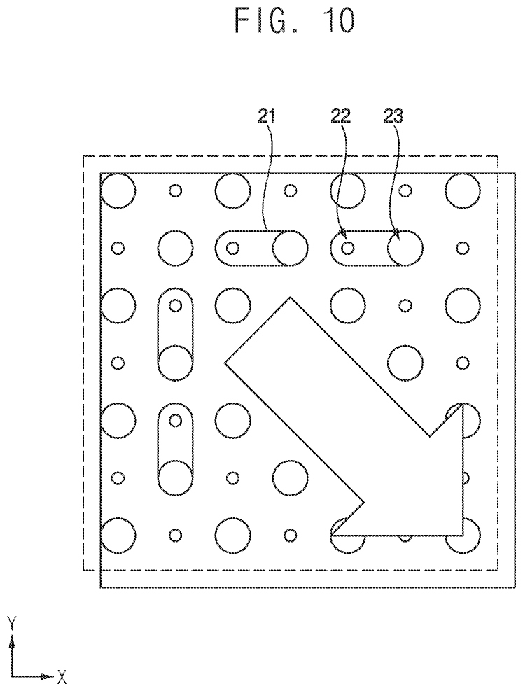

FIG. 8 is a diagram for explaining an example of an arrangement of positioning portions provided in the picker. In FIG. 8, the ejection holes BH, the suction holes VH and the positioning portion 20 are illustrated in simplified form for ease of description. FIG. 9 is a cross-sectional view taken along the line IX-IX in FIG. 8. FIG. 10 is a diagram for explaining an example of positioning the chip W1 by the positioning portion 20.

As illustrated in FIG. 8, the holding surface 15 may be provided with positioning portions 20 extending in a row in the X direction and in the Y direction, respectively. As illustrated in FIGS. 8 and 9, the positioning unit 20 may be provided with a plurality of grooves 21. The groove 21 may be an elongated circular groove disposed along a direction in which the positioning portion 20 extends in a longitudinal direction when viewed from a plan view. For example, a groove 21 may be elongated in the X direction for the positioning portion that extends in the X direction, and another groove 21 may be elongated in the Y direction for the positioning portion that extends in the Y direction. A size of the groove 21 may be, for example, 1.5 mm in length, 0.5 mm in width, and 0.1 mm in depth.

A gas supply hole 22 and an exhaust hole 23 may be provided in a bottom face of the groove 21. A size of the exhaust hole 23 may be larger than a size of the gas supply hole 22. The gas supply hole 22 may be circular with a diameter of 0.05 mm, for example. The exhaust hole 23 may be circular with a diameter of 0.5 m, for example.

A gas supply circuit may be connected to the gas supply hole 22. The supply circuits may include, for example, gas sources, pumps, valves, and the like. In addition, the gas supplied from the gas supply hole 22 may be an inert gas such as nitrogen. Additionally, the exhaust hole 23 may be connected to a negative pressure generating circuit including, for example, a vacuum pump, a valve, and the like. The gas supply hole 22 may supply gas, and the exhaust hole 23 may suction gas.

As indicated by arrows in FIG. 9, a gas flow in a certain direction may be formed in the groove 21. The chip W1 may be disposed to cover an upper portion of the positioning portion 20. The gas may flow along two adjacent sides of the substantially rectangular chip W1. The gas flow may apply a force to move the chip W1.

The movement direction of the chip W1 by the force for moving the chip W1 may be +X direction or −Y direction. Accordingly, as indicated by the large arrow in FIG. 10, the chip W1 vibrating without directionality may be moved from the position indicated by the broken line to the position indicated by the solid line. By continuously generating a force that moves the chip W1, it may be possible to align the chip W1 to a specific position in one direction. In addition, the moved chip W1 may stop at a position where a suction hole VH is provided in a region where the positioning portion 20 is not present.

If the chip W1 on the pick-up head 11 is not in a predetermined position, the positional relationship between the ejection holes BH and the suction holes VH controlling the warping of the chip W1 and the chip W1 changes, affecting the control performance. In addition, if vibration occurs while the chip W1 is floating, there is no means to stop the vibration, and there is a problem that transferring to the bonding head 3 may not be performed.

In contrast, in example embodiments, vibration of the chip W1 may be stopped by moving the chip W1 to a predetermined position on the pick-up head 11, and at the same time, the control performance of the warpage of the chip W1 may be improved. This makes it possible to perform high-quality mounting.

In addition, by using the positioning portion 20, even when the size of the chip W1 is reduced, vibration of the chip W1 may be suppressed without changing the configuration of the pick-up head 11, and accordingly, it becomes possible to perform alignment at a specific position.

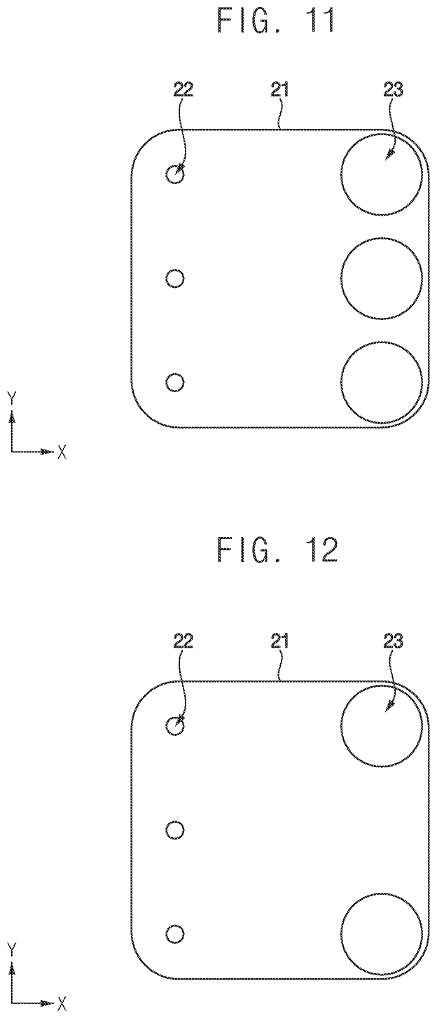

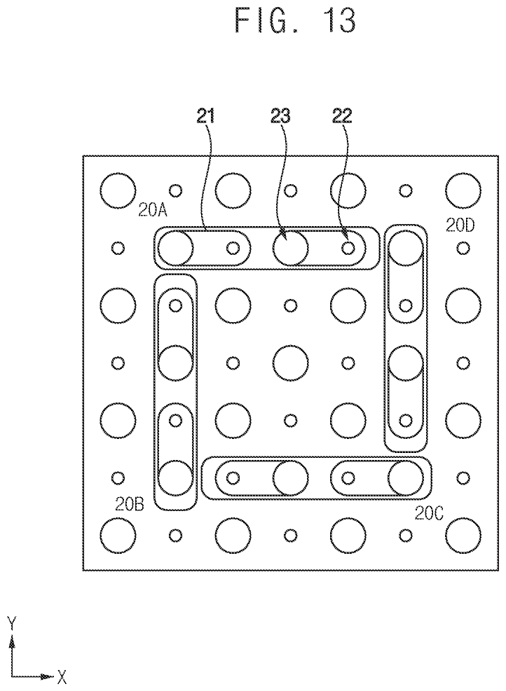

The shape of the groove 21 and the number or arrangement of the gas supply holes 22 and the exhaust holes 23 may not be limited to the above examples. In FIGS. 11 and 12, another example of the positioning portion 20 is shown. Here, a state in which one groove 21 is viewed from a plan view is shown. As shown in FIGS. 1I and 12, the groove 21 may have a square shape.

The number of the gas supply holes 22 and the exhaust holes 23 in one groove 21 may be the same or different. In the example shown in FIG. 11, three gas supply holes 22 may be arranged on the −X side or end of the groove 21, and three exhaust holes 23 may be arranged on the +X side or end of the groove 21. In the example shown in FIG. 12, three gas supply holes 22 may be arranged on the −X side or end of the groove 21, and two exhaust holes 23 may be arranged on the +X side or end of the groove 21. However, it may be necessary to satisfy the relationship ((gas supply flow rate through the gas supply hole 22)<(exhaust flow rate through the exhaust hole 23)).

In addition, the position where the positioning portion 20 is installed, and the number of positioning units 20 may not be limited to the above-described example. FIG. 13 is a diagram illustrating another example of arrangement of positioning portions. In the example shown in FIG. 13, four positioning portions 20A to 20D may be provided. The positioning portions 20A to 20D may be disposed adjacent edges of the rectangular holding surface 15, respectively, as illustrated. In the positioning portion 20A, a gas supply hole 22 may be provided in the +X direction in the groove 21, and an exhaust hole 23 may be provided in the −X direction.

In the positioning portion 20B, a gas supply hole 22 may be provided in the +Y direction in the groove 21, and an exhaust hole 23 may be provided in the −Y direction. In the positioning portion 20C, a gas supply hole 22 may be provided in the −X direction in the groove 21, and an exhaust hole 23 may be provided in the +X direction. In the positioning portion 20D, a gas supply hole 22 may be provided in the −Y direction in the groove 21, and an exhaust hole 23 may be provided in the +Y direction.

By controlling the positioning portions 20A to 20D, the moving direction of the chip W1 may be changed. For example, by turning on the positioning portions 20A and 20B and turning off the positioning portions 20C and 20D, the chip W1 may be moved to the lower left side. Further, by turning on the positioning portions 20A and 20D and turning off the positioning portions 20B and 20C, the chip W1 may be moved to the upper left side.

Additionally, by turning on the positioning portions 20B and 20C and turning off the position portions 20A and 20D, the chip W1 may be moved to the lower right side. Additionally, by turning on the positioning portions 20C and 20D and turning off the positioning portions 20A and 20B, the chip W1 may be moved to the upper right side.

The present inventive concept is not limited to the above example embodiments, and appropriate changes may be made without departing from the scope of the present inventive concept.

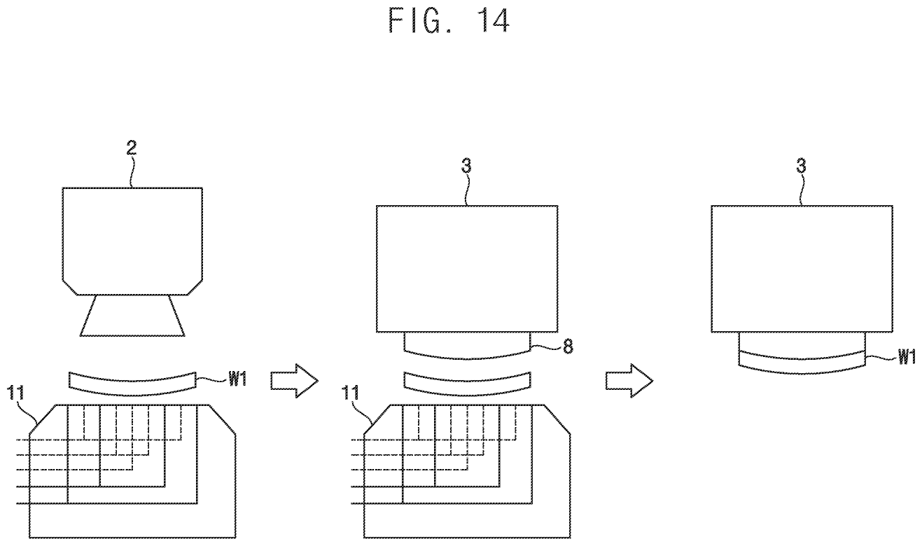

FIG. 14 is a diagram illustrating a method of manufacturing a semiconductor device in accordance with example embodiments. In FIG. 14, a feature different from FIG. 6 is the shape of an adsorption surface 8 of the bonding head 3. FIG. 14 shows, sequentially from the left, a state of measuring the surface shape of the chip W1 picked up by the picker 1, a state of transferring the chip W1 from the picker 1 to the bonding head 3, and a state in which the chip W1 is adsorbed and held by the bonding head 3.

In the example shown in FIG. 14, the bonding head 3 may have the adsorption surface 8 formed in a curved shape with the central lower portion as a vertex. By pressing the chip W1 against the substrate W2 from the apex of the bonding head 3 toward the outer periphery (edge portion), air present at the junction between the chip W1 and the substrate W2 may be extruded, and the occurrence of voids may be prevented.

In order to suppress the deformation of the chip W1 when the thin chip W1 is adsorbed by the bonding head 3, the adsorption surface 8 of the bonding head 3 may be often provided with a porous body. In the bonding head 3 having the porous body, the entire surface of the adsorption surface 8 may have an adsorption force. However, since the area of the adsorption hole is large, the adsorption force for adsorbing the chip W1 may be weakened. In particular, as shown in FIG. 14, when the gap between the adsorption surface 8 and the chip W1 is not uniform, the adsorption force of the chip W1 may be further weakened at a location where the gap is wide open.

Accordingly, as shown in FIG. 14, the controller 7 may control at least one of the gas supply flow rate of the ejection holes BH and the exhaust flow rate of the suction holes VH when the bonding head 3 receives the chip W1 from the pick-up head 11, to change the shape of the chip W1 to be matched with the shape of the suction surface 8 of the bonding head 3. For example, the controller 7 may deform the chip W1 to be in a curved shape with the central upper portion of the chip W1 as a vertex.

In this way, by deforming the chip W1 in a shape close to the shape of the adsorption surface 8, the gap between the chip W1 and the adsorption surface 8 may be reduced. Thus, the transfer of the chip W1 from the picker 1 to the bonding head 3 may be performed stably.

The above manufacturing apparatus may be used to manufacture semiconductor packages including logic devices and memory devices. For example, the semiconductor package may be applied to logic devices such as central processing units (CPUs), main processing units (MPUs), or application processors (APs), or the like, and volatile memory devices such as DRAM devices, SRAM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

1. A manufacturing apparatus for a semiconductor device, the manufacturing apparatus comprising:
a pick-up head comprising a holding surface configured to hold a bonding component, wherein the holding surface comprises a plurality of ejection holes through which gas is ejected, and a plurality of suction holes through which the gas is suctioned;
a warpage measurement device configured to measure warpage of the bonding component held by the pick-up head; and
a controller configured to control at least one of a supply flow rate of the gas ejected through the plurality of ejection holes and a suction flow rate of the gas suctioned through the plurality of suction holes in response to the measured warpage of the bonding component.

2. The manufacturing apparatus of claim 1, wherein the holding surface comprises a plurality of regions that are outwardly spaced from a center of the holding surface, and
wherein the controller controls the supply flow rate of the gas from the plurality of ejection holes and the suction flow rate from the plurality of suction holes for each of the plurality of regions.

3. The manufacturing apparatus of claim 1,
wherein the holding surface comprises a positioning portion having a gas supply hole and an exhaust hole, wherein the positioning portion is configured to position the bonding component by flowing gas from the gas supply hole to the exhaust hole.

4. The manufacturing apparatus of claim 3, wherein the positioning portion comprises a groove in the holding surface, and
wherein the gas supply hole and the exhaust hole are in the groove.

5. The manufacturing apparatus of claim 1, further comprising a bonding head configured to receive the bonding component from the pick-up head and bond the bonding component to a component,
wherein, when the bonding head receives the bonding component from the pick-up head, the controller is configured to control at least one of the supply flow rate and the suction flow rate to change a shape of the bonding component held by the pick-up head according to a shape of an adsorption surface of the bonding head.

6. A manufacturing apparatus for a semiconductor device, the manufacturing apparatus comprising a pick-up head configured to pick up and hold a bonding component, the pick-up head comprising a holding surface that is configured to adsorb and hold the bonding component, wherein the holding surface comprises a plurality of ejection holes through which gas is ejected, and a plurality of suction holes through which gas is suctioned, wherein the plurality of ejection holes and the plurality of suction holes are arranged in a plurality of regions of the holding surface, wherein the plurality of regions comprise a central region at a center of the holding surface and a plurality of spaced apart concentric regions extending around the central region.

7. The manufacturing apparatus of claim 6, wherein two or more ejection holes are adjacent each one of the plurality of suction holes in each of the plurality of regions.

8. The manufacturing apparatus of claim 6, wherein the plurality of spaced apart concentric regions comprise a first concentric region that is outwardly spaced apart from the central region and that extends around the central region.

9. The manufacturing apparatus of claim 8, wherein the plurality of spaced apart concentric regions further comprise second and third concentric regions, wherein the second concentric region is outwardly spaced apart from the first concentric region and extends around the first concentric region, and wherein the third concentric region is outwardly spaced apart from the second concentric region and extends around the second concentric region.

10. The manufacturing apparatus of claim 6, wherein the holding surface further comprises at least one positioning portion having at least one gas supply hole and at least one exhaust hole, wherein the at least one positioning portion is configured to position the semiconductor device by flowing gas from the at least one gas supply hole to the at least one exhaust hole.

11. The manufacturing apparatus of claim 10, wherein the at least one positioning portion comprises a first positioning portion that extends along a first direction, and a second positioning portion that extends along a second direction that is transverse to the first direction.

12. The manufacturing apparatus of claim 11, wherein the first positioning portion and the second positioning portion are each located between adjacent concentric regions.

13. The manufacturing apparatus of claim 10, wherein the at least one positioning portion comprises a groove in the holding surface, wherein the at least one gas supply hole and the at least one exhaust hole are in the groove, and wherein a size of the at least one exhaust hole is larger than a size of the at least one gas supply hole.

14. The manufacturing apparatus of claim 13, wherein the groove comprises opposite first and second ends, wherein the at least one gas supply hole comprises a plurality of gas supply holes adjacent the first end, and wherein the at least one exhaust hole comprises a plurality of exhaust holes adjacent the second end.

15. The manufacturing apparatus of claim 10, wherein the holding surface comprises opposite first and second edges, and opposite third and fourth edges, wherein the at least one positioning portion comprises a first positioning portion that extends along and is adjacent to the first edge, a second positioning portion that extends along and is adjacent to the second edge, a third positioning portion that extends along and is adjacent to the third edge, and a fourth positioning portion that extends along and is adjacent to the fourth edge.

16. A manufacturing apparatus for a semiconductor device, the manufacturing apparatus comprising:
a pick-up head comprising a holding surface configured to hold a bonding component, wherein the holding surface comprises a plurality of ejection holes through which gas is ejected, and a plurality of suction holes through which the gas is suctioned; and
a controller configured to control at least one of a supply flow rate of the gas ejected through the plurality of ejection holes and a suction flow rate of the gas suctioned through the plurality of suction holes,
wherein the plurality of ejection holes and the plurality of suction holes are arranged in a plurality of regions of the holding surface, and
wherein the plurality of regions are outwardly spaced from a center of the holding surface.

17. The manufacturing apparatus of claim 16, wherein the holding surface further comprises at least one positioning portion having at least one gas supply hole and at least one exhaust hole, wherein the at least one positioning portion is configured to position the semiconductor device by flowing gas from the at least one gas supply hole to the at least one exhaust hole.

18. The manufacturing apparatus of claim 17, wherein the at least one positioning portion comprises a groove in the holding surface, and wherein the at least one gas supply hole and the at least one exhaust hole are in the groove.

19. The manufacturing apparatus of claim 16, further comprising:
a warpage measurement device configured to measure warpage of the bonding component held by the pick-up head, wherein the controller controls the supply flow rate of the gas from the plurality of ejection holes and the suction flow rate from the plurality of suction holes for each of the plurality of regions in response to the measured warpage of the bonding component.

20. The manufacturing apparatus of claim 16, further comprising:
a bonding head configured to receive the bonding component from the pick-up head and bond the bonding component to a component.

21.-25. (canceled)
